(19) United States
(12) Patent Application Publication
(10) Pub. No.: US 2017/0069380 A1
(43) Pub. Date: Mar. 9, 2017

(54) MEMORY DEVICE

(71) Applicant: KABUSHIKI KAISHA TOSHIBA, Tokyo (JP)

(72) Inventor: Masahiro TAKAHASHI, Yokohama Kanagawa (JP)

(73) Assignee: KABUSHIKI KAISHA TOSHIBA, Tokyo (JP)

(21) Appl. No.: 15/062,093

(22) Filed: Mar. 5, 2016

Related U.S. Application Data
(60) Provisional application No. 62/214,535, filed on Sep. 4, 2015.

(51) Int. Cl. G11C 13/00

(52) U.S. Cl. CPC G11C 13/0069; G11C 13/004

(57) ABSTRACT

According to one embodiment, a memory device includes first and second memory cells including first and second transistors, respectively, and third and fourth transistors. First and second memory cells include first and second variable resistance elements, respectively. One end of the third and fourth transistors is connected to the first and second memory cells, respectively. First and second voltages are applied to a gate of the third and fourth transistors, respectively, during reading data of the first memory cell. The first voltage is higher than the second voltage. Third and second voltages are applied to a gate of the third and fourth transistors, respectively, during writing data of the first memory cell. The first voltage is lower than the third voltage.

### CROSS-REFERENCE TO RELATED APPLICATIONS

This application claims the benefit of U.S. Provisional Application No. 62/214,535, filed Sep. 4, 2015, the entire contents of which are incorporated herein by reference.

### FIELD

Embodiments described herein relate generally to a memory device.

### BACKGROUND

A resistance change type memory is known as a kind of memory device. In addition, a magnetic random access memory (MRAM) is known as a kind of resistance change type memory. The MRAM is a memory device which employs a magnetic element having a magnetoresistive effect as a memory cell which stores information. The MRAM attracts attention as a next-generation memory device having features of a high-speed operation, a large capacity and nonvolatility. Besides, the MRAM has steadily been researched and developed as a replacement for a volatile memory such as a DRAM or SRAM.

### BRIEF DESCRIPTION OF THE DRAWINGS

FIG. 1 is a block diagram illustrating the configuration of a memory device according to a first embodiment;

FIG. 2 is a circuit diagram of a memory cell which the memory device according to the first embodiment includes;

FIG. 3 is a cross-sectional view of an MTJ element which the memory device according to the first embodiment includes;

FIG. 4 is a circuit diagram of a memory cell array which the memory device according to the first embodiment includes;

FIG. 5 is a circuit diagram of a sense amplifier and a write driver which the memory device according to the first embodiment includes;

FIG. 6 is a timing chart illustrating a write operation of the memory device according to the first embodiment;

FIG. 7 is a circuit diagram of the sense amplifier and write driver which the memory device according to the first embodiment includes;

FIG. 8 is a timing chart illustrating a write operation of the memory device according to the first embodiment;

FIG. 9 is a circuit diagram of the sense amplifier and write driver which the memory device according to the first embodiment includes;

FIG. 10 is a timing chart illustrating a read operation of the memory device according to the first embodiment;

FIG. 11 is a circuit diagram of the sense amplifier and write driver which the memory device according to the first embodiment includes;

FIG. 12 is a timing chart illustrating a read operation of a memory device according to a second embodiment.

FIG. 13 is a circuit diagram of a sense amplifier and a write driver which the memory device according to the second embodiment includes;

FIG. 14 is a timing chart illustrating a read operation of a memory device according to a third embodiment.

FIG. 15 is a circuit diagram of a sense amplifier and a write driver which the memory device according to the third embodiment includes;

FIG. 16 is a timing chart illustrating a read operation of a memory device according to a fourth embodiment; and

FIG. 17 and FIG. 18 are circuit diagrams of sense amplifiers and write drivers which the memory devices according to the fourth and fifth embodiments include.

### DETAILED DESCRIPTION

In general, according to one embodiment, a memory device includes first and second memory cells including first and second transistors, respectively, and third and fourth transistors. First and second memory cells include first and second variable resistance elements, respectively. One end of the third and fourth transistors is connected to the first and second memory cells, respectively. First and second voltages are applied to a gate of the third and fourth transistors, respectively, during reading data of the first memory cell. The first voltage is higher than the second voltage. Third and second voltages are applied to a gate of the third and fourth transistors, respectively, during writing data of the first memory cell. The first voltage is lower than the third voltage.

Embodiments will be described hereinafter with reference to the accompanying drawings. Incidentally, in the description below, structural elements having substantially identical functions and configurations are denoted by like reference numerals. The drawings are schematic ones. Each of the embodiments is intended to illustrate a device and a method for embodying the technical concept of the embodiment, and the technical concept of each embodiment does not restrict the materials, shapes, configurations, dispositions, etc. of the structural parts to those described below.

In the following embodiments, as a memory device, a magnetoresistive random access memory (MRAM), which is a kind of resistance change type memory, is described by way of example.

### [1] First Embodiment

In a memory device 1 according to a first embodiment, in a data read operation, a column select signal CSLU, which is input to a column select transistor SWU that is connected to a global bit line GBL, is set at an intermediate voltage.

[1-1] Configuration

[1-1-1] Entire Configuration

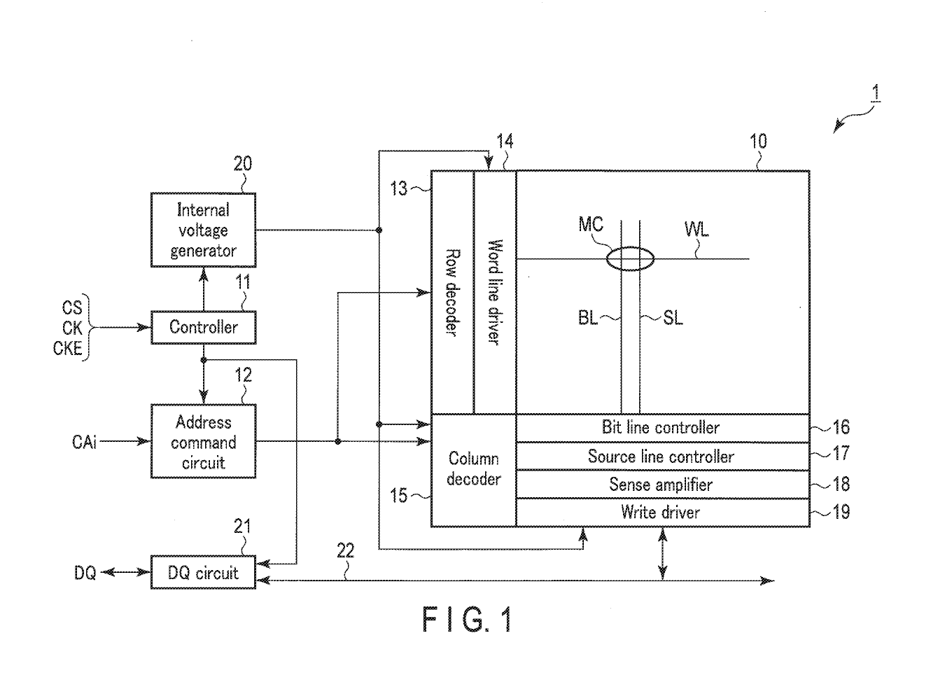

Referring to FIG. 1, the entire configuration of the memory device 1 according to the first embodiment is described.

The memory device 1 includes a memory cell array 10, a controller 11, an address reception circuit 12, a row decoder 13, a word line driver 14, a column decoder 15, a bit line controller 16, a source line controller 17, a sense amplifier 18, a write driver 19, a voltage generator 20, and a data input/output (DQ) circuit 21.

The memory cell array 10 includes a plurality of memory cells MC. In the memory cell array 10, in order to control voltages which are applied to the memory cells MC, a plurality of bit lines BL, a plurality of source lines SL and a plurality of word lines WL are provided. The bit lines BL and source lines SL are provided in a column direction. The word lines are provided in a row direction which is perpendicular to the column direction. The memory cell MC is provided in association with a pair of the bit line BL and source line SL, and the word line WL.

The controller 11 is connected to an external controller or a host device (not shown), and receives external control signals. The external control signals include a chip select signal CS, a clock signal CK, and a clock enable signal CKE. In addition, the controller 11 controls the address reception circuit 12, voltage generator 20 and DQ circuit 21 in accordance with the respective control signals.

The address reception circuit 12 is connected to the external controller or host device, and receives an address signal CA. In addition, the address reception signal 12 sends the address signal CA to the row decoder 13 or column decoder 15 in accordance with a signal received from the controller 11.

The row decoder 13 decodes a row address of the received address signal CA. In addition, the row decoder 13 controls the word line driver 14, based on the decoded result.

The word line driver 14 is connected to plural word lines WL. In addition, the word line driver 14 selects a word line WL in accordance with the signal received from the row decoder 13, and applies a voltage to the selected word line WL.

The column decoder 15 decodes a column address of the received address signal CA. In addition, the column decoder 15 controls the bit line controller and source line controller 17, based on the decoded result.

The bit line controller 16 is connected to plural bit lines BL. In addition, the bit line controller 16 selects a bit line BL in accordance with the signal received from the column decoder 15.

The source line controller 17 is connected to plural source lines SL. In addition, the source line controller 17 selects a source line SL in accordance with the signal received from the column decoder 15.

The sense amplifier 18 is connected to the bit lines BL via the bit line controller 16. In addition, the sense amplifier 18 senses data which was read from a selected memory cell MC to the bit line BL, and reads the data stored in the memory cell MC.

The write driver 19 is connected to the bit lines BL via the bit line controller 16, and is connected to the source lines SL via the source line controller 17. In addition, by causing current to flow to the selected memory cell MC, the write driver 19 writes write data, which is sent from the DQ circuit 21, to the memory cell MC.

The voltage generator 20 generates voltages which are necessary for data write, read and erase in accordance with control signals that are sent from the controller 11, and supplies the voltages to the memory cell array 10, word line driver 14, and sense amplifier 18 and write driver 19. Thereby, necessary voltages for various operations are applied to the bit lines BL, source lines SL and word lines WL.

The DQ circuit 21 is connected to the external controller or host device, and sends/receives data to/from the outside. Write data, which was input from the outside, is sent from the DQ circuit 21 to the write driver 19 via a data bus 22. Read data, which was read by the sense amplifier 18, is sent to the DQ circuit 21 via the data bus 22, and is output to the outside from the DQ circuit 21.

Furthermore, the configuration of the memory device 1 is not limited to the above, and various forms may be adopted. For example, the sense amplifier 18 and write driver 19 may include a page buffer. The page buffer temporarily stores write data, which is sent from the DQ circuit 21, at a time of data write, and temporarily stores read data, which is sent from the memory cell array 10, at a time of data read.

[1-1-2] Memory Cell MC

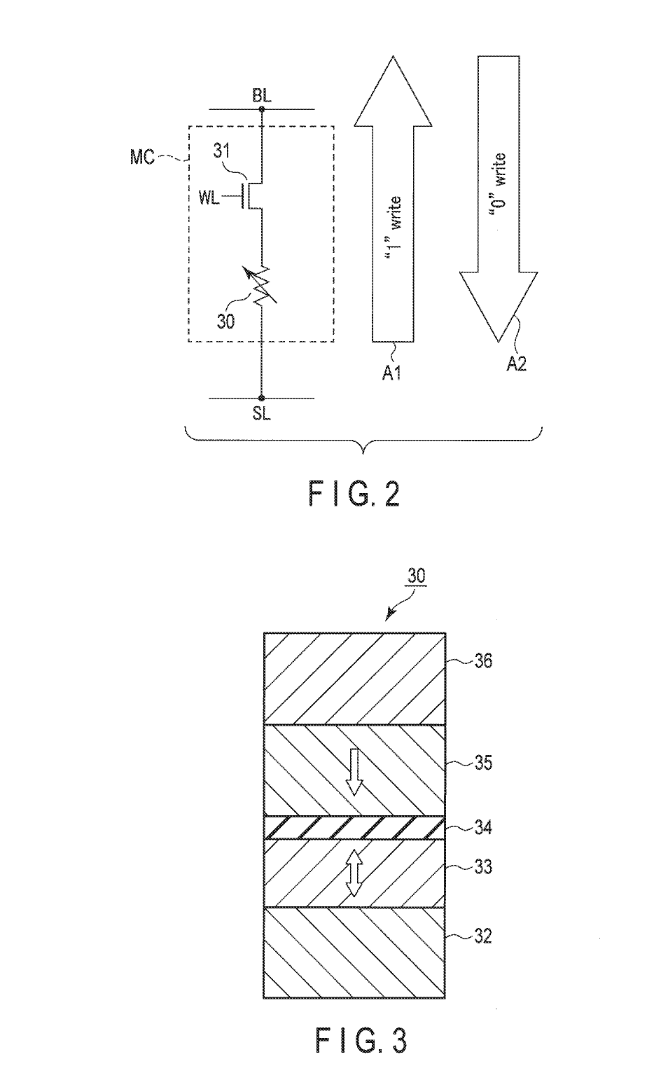

Referring to FIG. 2, the configuration of the memory cell MC is described by taking a spin-transfer write type MRAM as an example. In the spin-transfer write type MRAM, the magnetization direction of the memory cell MC is controlled by causing an electric current to directly flow in the memory cell MC.

The memory cell MC includes a memory element 30 and a cell select transistor 31.

The memory element 30 is a variable resistance element and is, for instance, an MTJ element utilizing a tunneling magnetoresistive (TMR) effect. The memory element 30 has two states, namely a high-resistance state and a low-resistance state, and can store 1-bit data by defining the high-resistance state and low-resistance state as data “1” and data “0”, respectively. Then, the state of the memory element 30 can be made to transition between the low-resistance state and high-resistance state by causing current to flow through the memory element 30. For example, in a write operation, the memory element 30 transitions to the high-resistance state if current is caused to flow in the direction of arrow A1 (“1” write), and the memory element 30 transitions to the low-resistance state if current is caused to flow in the direction of arrow A2 (“0” write). Incidentally, how to allocate data to the resistance states of the memory element 30 is arbitrarily settable.

The cell select transistor 31 is, for example, an n-channel MOS transistor, and is provided for each memory cell MC. The cell select transistor 31 is used for selecting the memory cell MC, and is configured to enter an ON state when current is caused to flow through the associated memory element 30.

The memory element 30 and cell transistor 31 are connected in series between the bit line BL and source line SL. One end of the memory element 30 is connected to the source line SL, and the other end of the memory element 30 is connected to one end of the cell select transistor 31. The other end of the cell select transistor 31 is connected to the bit line BL, and the gate of the cell select transistor 31 is connected to the word line WL. Incidentally, the order of connection of the memory element 30 and select transistor 31 may be reversed, and is not limited to this example. In this case, one end of the memory element 30 is connected to the bit line BL, and the other end of the memory element 30 is connected to one end of the cell select transistor 31. The other end of the cell select transistor 31 is connected to the source line SL.

Furthermore, as the memory cell MC, use may be made of resistance change type memories, such as resistance random access memory (ReRAM), phase-change RAM (PRAM), ferroelectric NAND-type memory (FeNAND), magnetic random access memory (MRAM) and interfacial phase-change memory (iPCM).

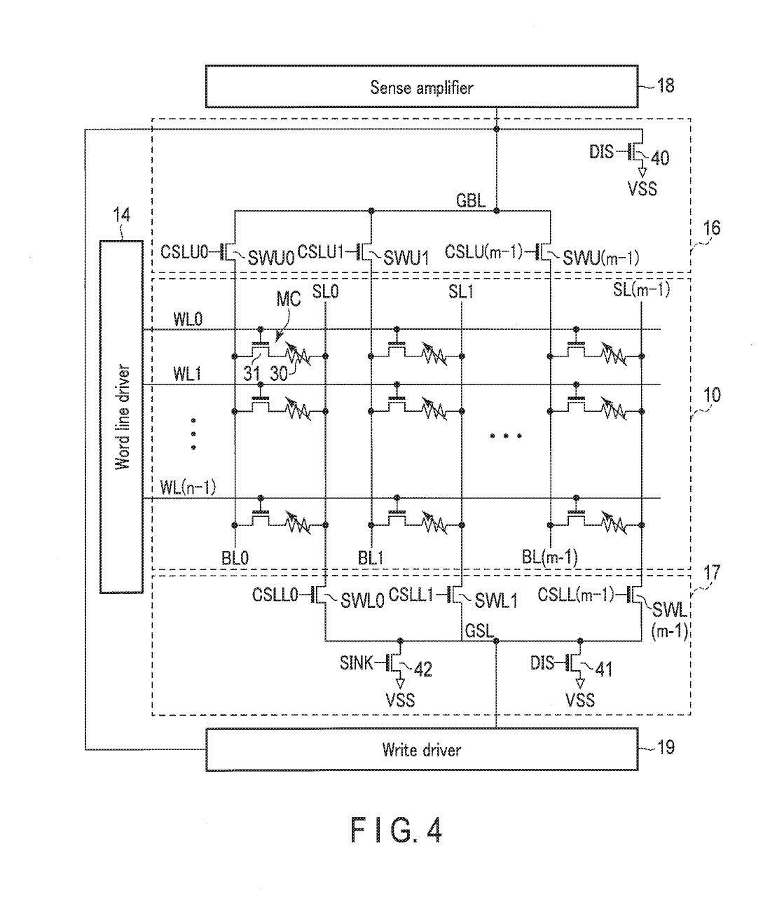

Referring to FIG. 3, a description is given of the configuration of an MTJ element 30 as an example of the memory element 30.

The MTJ element 30 is configured such that a bottom electrode 30, a memory layer (free layer) 33, a nonmagnetic layer (tunnel barrier layer) 34, a reference layer (fixed layer) 35 and a top electrode 36 are stacked in the named order.

Each of the memory layer 33 and reference layer 35 is a vertical magnetization film which is formed of a ferromagnetic material and has a magnetic anisotropy that is parallel to the direction of stacking of layers. A magnetization reversal current of the memory layer 33 is less than a magnetization reversal current of the reference layer 35. Thereby, the magnetization direction of the memory layer 33 is variable by a predetermined write current, and the magnetization direction of the reference layer 35 is invariable by the predetermined write current. The tunnel barrier layer 34 is formed of an insulative material, and functions as a barrier between the memory layer 33 and reference layer 35. Each of the bottom electrode 32 and top electrode 36 is formed of a metal, and is used for connection to a circuit utilizing the MTJ element 30.

The resistance value of the MTJ element 30 varies depending on the magnetization directions of the memory layer 33 and reference layer 35. The MTJ element 30 is in a low-resistance state when the magnetization directions of the memory layer 33 and reference layer 35 are parallel, and the MTJ element 30 is in a high-resistance state when the magnetization directions of the memory layer 33 and reference layer 35 are antiparallel.

The magnetization directions of the memory layer 33 and reference layer 35 become antiparallel when a write current is caused to flow in a direction from the reference layer 35 to the memory layer 33, and become parallel when a write current is caused to flow in a direction from the memory layer 33 to the reference layer 35. Thereby, the MTJ element 30 can be used as a memory element which can store data of 1 bit.

Furthermore, when data of the memory cell MC is read, the sense amplifier 18 detects the resistance state of the MTJ element 30, based on a read current which flows through the MTJ element 30. The read current is set at a sufficiently smaller value than the magnetization reversal current of the memory layer 33.

In addition, the multilayer structure of the MTJ element 30 is not limited to this, and various forms may be adopted. For example, the order of stacking of the memory layer 33 and reference layer 35 may be reversed. Besides, an in-plane magnetization film having a magnetic anisotropy, which is perpendicular to the direction of stacking of layers, may be used for each of the memory layer 33 and reference layer 35.

[1-1-3] Memory Cell Array 10, Bit Line Controller 16 and Source Line Controller 17

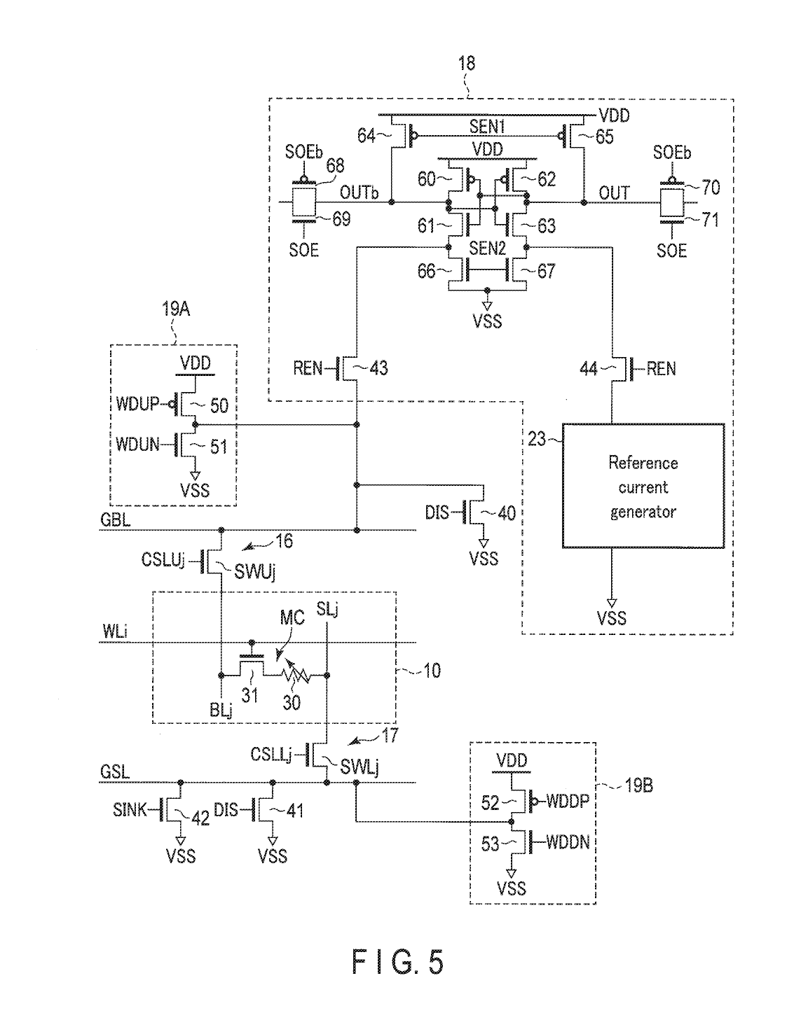

Referring to FIG. 4, a description is given of the circuit configurations of the memory cell array 10, bit line controller 16 and source line controller 17.

The memory cell array 10 is disposed between the bit line controller 16 and source line controller 17. The bit line controller 16 is connected to the sense amplifier 18 and write driver 19 via a global bit line GBL. The source line controller 17 is connected to the sense amplifier 18 via a global source line GSL. The configurations of these components will be described below in detail.

In the memory cell array 10, a plurality of memory cells MC are arranged in a matrix. In the memory cell array 10, there are provided an n-number (n is a natural number of 1 or more) of word lines WL (word lines WL0 to WL(n−1)), an m-number of bit lines BL (bit lines BL0 to BL(m−1)), and an m-number (m is a natural number of 1 or more) of source lines SL (source lines SL0 to SL(m−1)). Plural memory cells MC, which are arranged in the row direction, are connected to one word line WL. Plural memory cells MC, which are arranged in the column direction, are connected to one pair composed of one bit line BL and one source line SL.

The bit line controller 16 includes an m-number of column select transistors SWU (column select transistors SWU0 to SWU(m−1)), and a transistor 40.

The sources of the column select transistors SWU0 to SWU(m−1) are connected to the bit lines BL0 to BL(m−1), respectively. Column select signals CSLU0 to CSLU(m−1) are input to the gates of the column select transistors SWU0 to SWU(m−1), respectively.

The transistor 40 electrically connects the global bit line GBL to a ground terminal in accordance with a discharge signal DIS. The discharge signal DIS is a signal which is issued by the controller 11. The drain of the transistor 40 is connected to the global bit line GBL, the source of the transistor 40 is connected to the ground terminal, and the discharge signal DIS is input to the gate of the transistor 40.

The source line controller 17 includes an m-number of column select transistors SWL (column select transistors SWL0 to SWL(m−1)), and transistor 41 and 42.

The drains of the column select transistors SWL0 to SWL(m−1) are connected to the source lines SL0 to SL(m−1), respectively. Column select signals CSLL0 to CSLL(m−1) are input to the gates of the column select transistors SWL0 to SWL(m−1), respectively.

The transistor 41 electrically connects the global source line GSL to a ground terminal in accordance with a discharge signal DIS. The drain of the transistor 41 is connected to the global source line GSL, the source of the transistor 41 is connected to the ground terminal, and a discharge signal DIS is input to the gate of the transistor 41.

The transistor 42 electrically connects the global source line GSL to the ground terminal in accordance with a sink signal SINK. The sink signal SINK is a signal which is issued by the controller 11. The drain of the transistor 42 is connected to the global source line GSL, the source of the transistor 42 is connected to the ground terminal, and the sink signal SINK is input to the gate of the transistor 42.

The global bit line GBL is connected to the drains of the column select transistors SWU0 to SWU(m−1). Specifically, the bit lines BL0 to BL(m−1) are connected to the global bit line GBL via the column select transistors SWU0 to SWU(m−1).

The global source line GSL is connected to the sources of the column select transistors SWL0 to SWL(m−1). Specifically, the source lines SL0 to SL(m−1) are connected to the global source line GSL via the column select transistors SWL0 to SWL(m−1).

Furthermore, a ground voltage VSS of the memory device 1 is applied to the sources of the transistors 40, 41 and 42. VSS is, for example, 0 V.

Additionally, the configuration of the memory cell array 10 is not limited to this, and various forms may be adopted. For example, as the element that is used for selecting the memory cell, a diode may be substituted for the cell select transistor 31.

[1-1-4] Sense Amplifier 18 and Write Driver 19

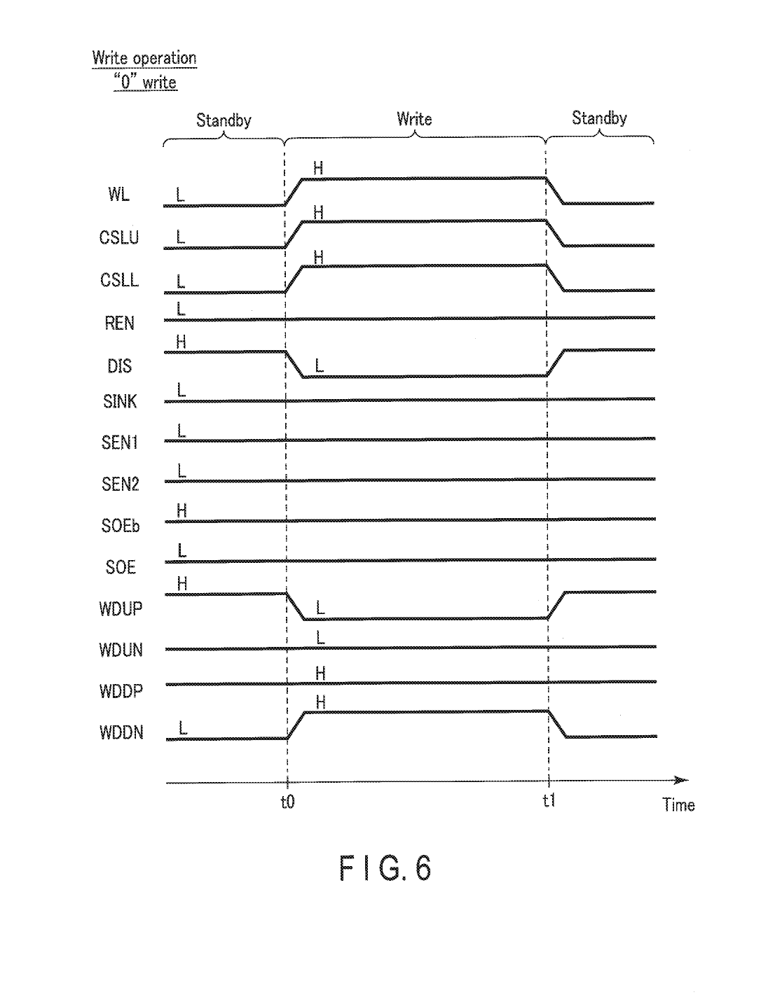

Referring to FIG. 5, the circuit configurations of the sense amplifier 18 and write driver 19 are described. Here, the sense amplifier 18 is a current detection-type sense amplifier. In the memory cell array 10 in FIG. 5, one memory cell MC, which corresponds to a word line WLi (i is an integer of 0 or more) and a set of a bit line BLj and a source line SLj (j is an integer of 0 or more), is illustrated. Similarly, the bit line controller 16 and source line controller 17 are illustrated by extracting column select transistors SWUj and SWLj corresponding to the memory cell MC that is illustrated.

To begin with, the circuit configuration of the sense amplifier 18 is described. The sense amplifier 18 includes transistors 43, 44, and 60 to 71, and a reference current generator 23.

The p-channel MOS transistor 60 and n-channel MOS transistor 61 function as a first inverter, and the p-channel MOS transistor 62 and n-channel MOS transistor 63 function as a second inverter.

The drain of the transistor 60 is connected to a power supply terminal. The drain of the transistor 61 is connected to the source of the transistor 60, and functions as an input node of the first inverter. The gate of the transistor 61 is connected to the gate of the transistor 60, and functions as an output node of the first inverter.

The drain of the transistor 62 is connected to the power supply terminal. The drain of the transistor 63 is connected to the source of the transistor 62, and functions as an input node of the second inverter. The gate of the transistor 63 is connected to the gate of the transistor 62, and functions as an output node of the second inverter.

The output node of the first inverter is connected to the input node of the second inverter, and the input node of the first inverter is connected to the output node of the second inverter. Thereby, the first inverter and second inverter function as a data hold circuit and can determine the data that was read from the memory cell MC. The input node of the first inverter is connected to a node OUTb, and the input node of the second inverter is connected to a node OUT.

The p-channel MOS transistors 64 and 65 function as a first sense circuit, and charge the nodes OUT, OUTb. The drain of the transistor 64 is connected to the power supply terminal, and the source of the transistor 64 is connected to the node OUTb. The drain of the transistor 65 is connected to the power supply terminal, and the source of the transistor 65 is connected to the node OUT. A sense enable signal SEN1 is input to the gates of the transistors 64 and 65. The sense enable signal SEN1 is a signal which is issued by the controller 11.

The n-channel MOS transistors 66 and 67 function as a second sense circuit, and amplify a difference between a read current and a reference current (to be described later in detail). The drain of the transistor 66 is connected to the source of the transistor 61, and the source of the transistor 66 is connected to a ground terminal. The drain of the transistor 67 is connected to the source of the transistor 63, and the source of the transistor 67 is connected to the ground terminal. A sense enable signal SEN2 is input to the gates of the transistors 66 and 67. The sense enable signal SEN2 is a signal which is issued by the controller 11.

The p-channel MOS transistor 68 and n-channel MOS transistor 69 function as a first output element, and output the data that is held in the data hold circuit. The paired transistor 68 and transistor 69 are connected in parallel. The drains of the transistor 68 and transistor 69 are connected to the node OUTb, and output enable signals SOEb and SOE are input to the gates of the transistor 68 and transistor 69, respectively. The output enable signals SOEb and SOE are signals which are issued by the controller 11.

The p-channel MOS transistor 70 and n-channel MOS transistor 71 function as a second output element, and output the data that is held in the data hold circuit. The paired transistor 70 and transistor 71 are connected in parallel. The drains of the transistor 70 and transistor 71 are connected to the node OUT, and output enable signals SOEb and SOE are input to the gates of the transistor 70 and transistor 71, respectively.

The n-channel MOS transistors 43 and 44 are set in the ON state at a time of a read operation, and electrically connect the sense amplifier 18 and memory cell array 10 and electrically connect the sense amplifier 18 and reference current generator 23. The drain of the transistor 43 is connected to the source of the transistor 61, the source of the transistor 43 is connected to the global bit line GBL, and a read enable signal REN is input to the gate of the transistor 43. The read enable signal REN is a signal which is issued by the controller 11 and instructs the start of the read operation. The drain of the transistor 44 is connected to the source of the transistor 63, the drain of the transistor 44 is connected to the reference current generator 23, and a read enable signal REN is input to the gate of the transistor 44.

The reference current generator 23 generates a reference current having an intermediate current value between the cell current flowing when the memory cell stores “1” data and the cell current flowing when the memory cell stores “0” data. The reference current generator 23 includes, for example, a reference cell in which “1” data is stored, and a reference cell in which “0” data is stored, and generates the reference current by using these reference cells. Furthermore, the configuration of the reference current generator 23 is not limited to this, and may generate a reference current by, for example, a fixed resistor.

Next, the circuit configuration of the write driver 19 is described. The write driver 19 is classified into a write driver 19A which is connected to the global bit line GBL, and a write driver 19B which is connected to the global source line GSL.

The write driver 19A includes a p-channel MOS transistor 50 and an n-channel MOS transistor 51. The drain of the transistor 50 is connected to a power supply terminal, and a write signal WDUP is input to the gate of the transistor 50. The write signal WDUP is a signal which is issued by the controller 11. The drain of the transistor 51 is connected to the source of the transistor 50, the source of the transistor 51 is connected to a ground terminal, and a write signal WDUN is input to the gate of the transistor 51. The write signal WDUN is a signal which is issued by the controller 11. The global bit line GBL is connected to the source of the transistor 50.

The write driver 19B includes a p-channel MOS transistor 52 and an n-channel MOS transistor 53. The drain of the transistor 52 is connected to a power supply terminal, and a write signal WDDP is input to the gate of the transistor 52. The write signal WDDP is a signal which is issued by the controller 11. The drain of the transistor 53 is connected to the source of the transistor 52, the source of the transistor 53 is connected to a ground terminal, and a write signal WDDN is input to the gate of the transistor 53. The write signal WDDN is a signal which is issued by the controller 11. The global source line GSL is connected to the source of the transistor 52.

Furthermore, a power supply voltage VDD of the memory device 1 is applied to the drains of the transistors 50, 52, 64 and 65. VDD is, for example, 1.2 V. The voltage, which is applied to the sources of the transistors 51, 53, 66 and 67, and the ground terminal connected to the reference current generator 23, is VSS.

Besides, the configurations of the sense amplifier 18 and write driver 19 are not limited to the above, and various forms may be adopted.

[1-2] Operations

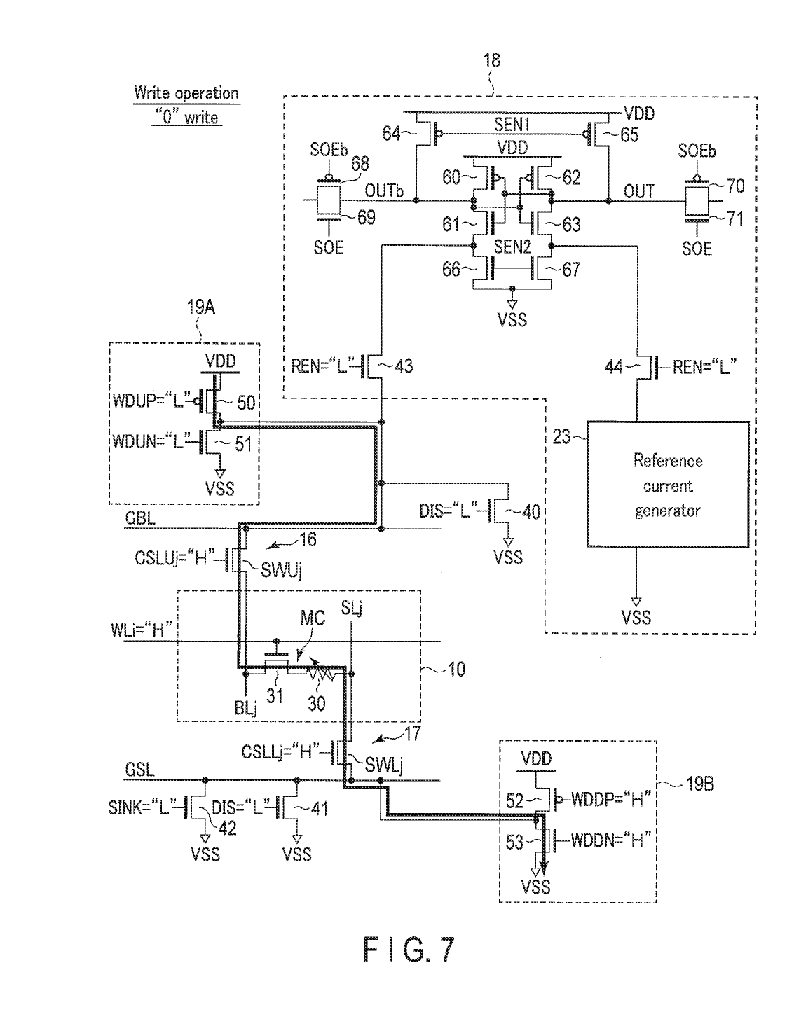

Referring to FIG. 6 to FIG. 11, the write operation and read operation of the memory device 1 according to the first embodiment are described. In the description below, the case is illustrated, by way of example, in which a memory cell corresponding to a word line WLn and a pair of a bit line BLm and a source line SLm were selected. The column select signals CSLU, CSLL corresponding to the selected memory cell MC are set in the ON state, and the column select signals CSLU, CSLL corresponding to non-selected memory cells MC are set in the OFF state.

[1-2-1] Write Operation

Referring to FIG. 6, a description is given of the write operation of the memory device in a case of writing data “0” in the memory cell MC.

To begin with, a standby state prior to the write operation is described.

In the standby state, the controller 11 sets the voltage of the word line WL and the column select signals CSLU, CSLL at “L” level. Accordingly, the cell select transistor 31 and column select transistors SWU, SWL enter the OFF state, and the memory cell MC is set in the non-selected state.

In addition, the controller 11 sets the discharge signal DIS at logic “H” level. Accordingly, the transistors 40 and 41 enter the ON state, and the global bit line GBL and global source line GSL are electrically connected to the ground terminal. Thereby, the voltage of the memory cell array 10 is set at the ground voltage, and the memory cell array 10 enters the floating state, and is prevented from being affected by coupling, etc.

In addition, the controller 11 sets the write signals WDUN, WDDN at logic “L” level, and sets the write signal WDUP, WDDP at “H” level. Accordingly, the transistors 51 to 54 enter the OFF state, and the write drivers 19A and 19B are set in the inactive state.

Additionally, the controller 11 sets the sense enable signals SEN1, SEN2 at logic “L” level. Accordingly, since the transistors 64 and 65 are in the ON state, the first sense circuit charges the nodes OUT, OUTb. The transistors 66 and 67 enter the OFF state, and the second sense circuit is sent in the inactive state.

Additionally, the controller 11 sets the output enable signals SOEb and SOE at logic “H” level and logic “L”, respectively. Accordingly, the transistors 68 to 71 enter the OFF state, and the first and second output elements are set in the inactive state.

Additionally, the controller 11 sets the read enable signal REN at logic “L” level. Accordingly, the transistors 43, 44 enter the OFF state, and the current path between the sense amplifier 18 and memory cell array 10 and the current path between the sense amplifier 18 and reference current generator 23 are disconnected.

Additionally, the controller 11 sets the sink signal SINK at logic “L” level. Accordingly, the transistor 42 enters the OFF state, and the current path between the global source line GSL and ground terminal is disconnected.

In the standby state, the nodes OUT and OUTb are supplied with current from the power supply terminal that is connected to the first sense circuit.

Next, the write operation of data “0” is described.

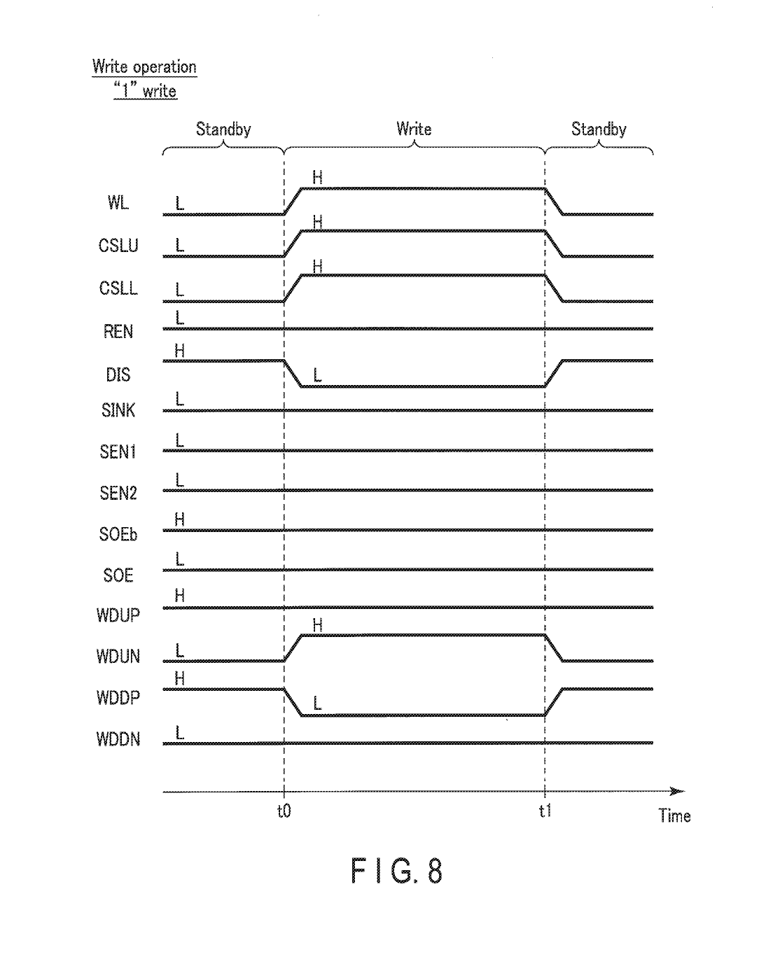

At time instant t0, the controller 11 sets the word line WL and column select signals CSLU, CSLL at “H” level, and sets the cell select transistor 31 and column select transistors SWU, SWL in the ON state. Thereby, a memory cell, in which data is to be written, is selected. In addition, the controller 11 sets the discharge signal DIS at “L” level, and sets the transistors 40 and 41 in the OFF state. Thereby, the memory cell array 10 enters the active state. Furthermore, the controller 11 sets the write signal WDUP at “L” level and the write signal WDDN at “H” level, and sets the transistors 50 and 53 in the ON state. Thereby, the write drivers 19A, 19B enter the active state. At this time, as illustrated in FIG. 7, since write current flows from the write driver 19A to the write driver 19B, write of data “0” is executed in the memory cell MC.

At time instant t1, the controller 11 sets the discharge signal DIS at “H” level, and sets the transistors 40 and 41 in the ON state. In addition, the controller 11 sets the word line WL and the column select signals CSLU and CSLL at “L” level, and sets the cell select transistors 31 and column select transistors SWU and SWL in the OFF state. In addition, the controller 11 sets the write signal WDUP at “H” level and the write signal WDDN at “L” level, and sets the transistors 50 and 53 in the OFF state. Thereby, the memory device 1 enters a standby state and completes the write operation.

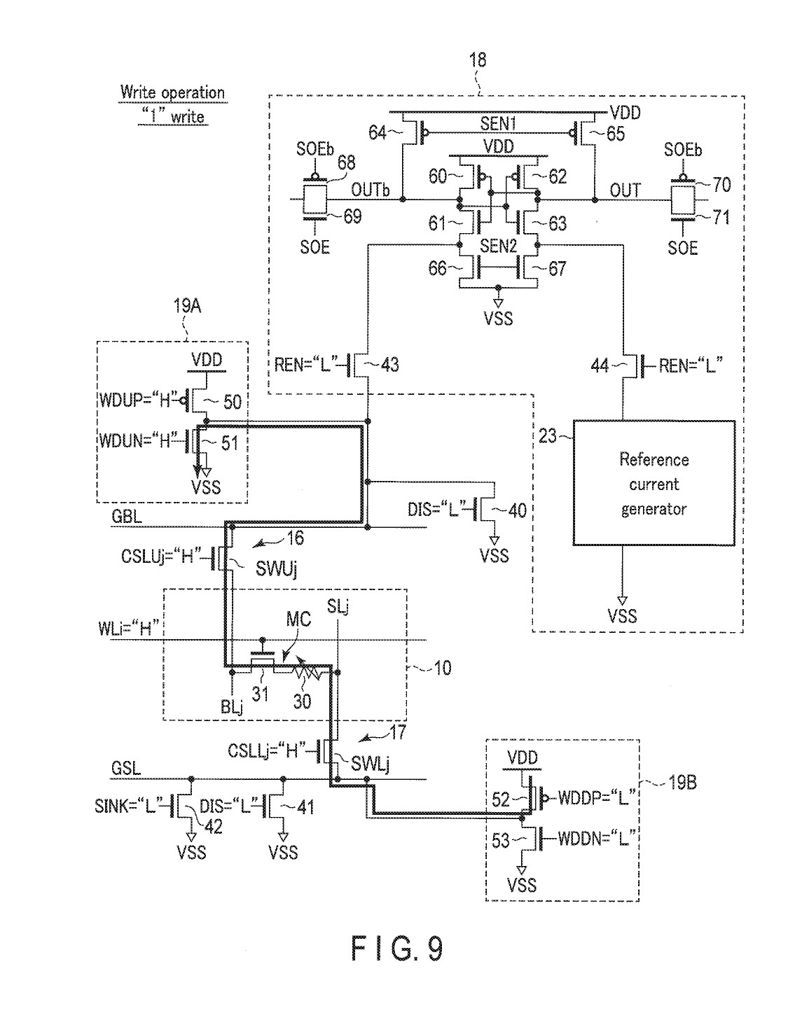

Referring to FIG. 8, a description is given of the write operation of the memory device 1 in a case of writing data “1” in the memory cell MC. Only the points, which are different from the case of writing data “0”, will be described.

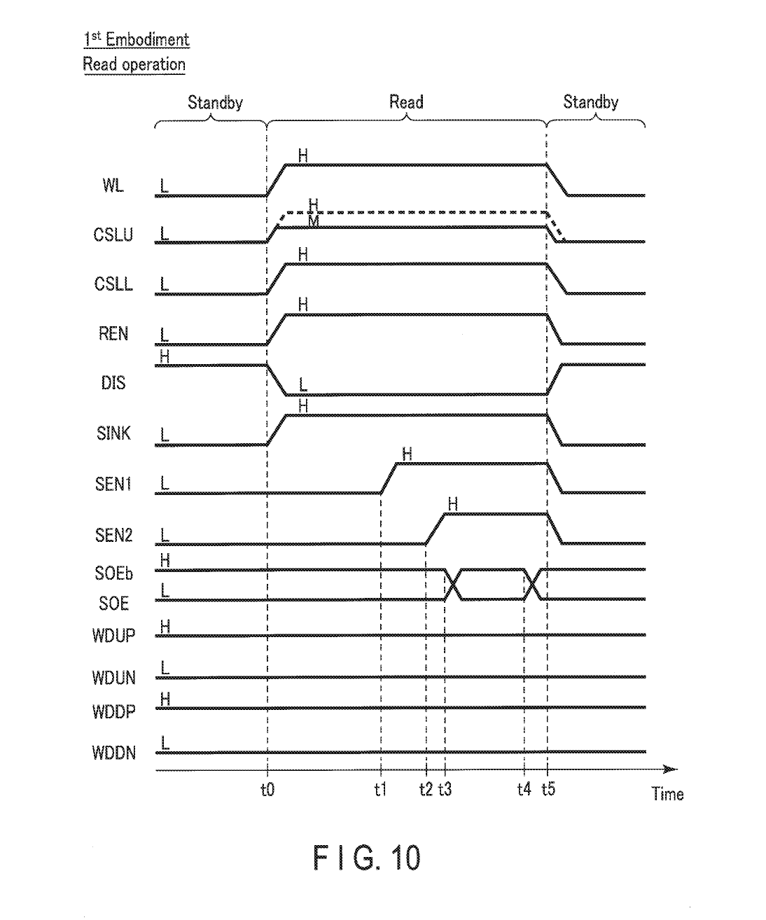

At time point t0, the controller 11 sets the write signal WDUN at “H” level and the write signal WDDP at “L” level, and sets the transistors 51 and 52 in the ON state. Thereby, the write driver 19A and 19B enter the active state. At this time, as illustrated in FIG. 9, since write current flows from the write driver 19B to the write driver 19A, write of data “1” is executed in the memory cell MC.

At time instant t1, the controller 11 sets the write signal WDUN at “L” level and the write signal WDDP at “H” level, and sets the transistors 51 and 52 in the OFF state. Thereby, the memory device 1 enters a standby state and completes the write operation.

Furthermore, the signal of “H” level is, for example, the power supply voltage VDD, and the signal of “L” level is, for example, the ground voltage VSS.

[1-2-2] Read Operation

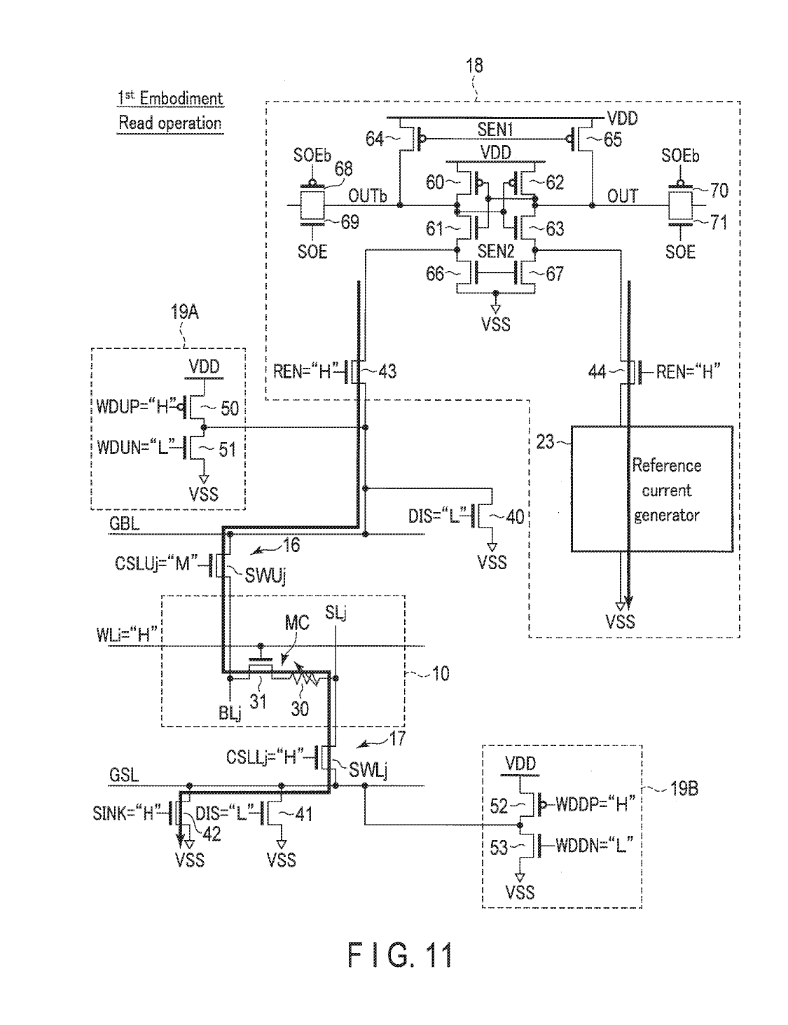

Referring to FIG. 10, a description is given of the read operation of the memory device 1.

At time instant t0, the controller 11 sets the word line WL and column select signal CSLL at “H” level, sets the column select signal CSLU at logic “M” level, and sets the cell select transistor 31 and column select transistors SWU and SWL in the ON state. Thereby, a memory cell, from which data is to be read, is selected. The voltage of “M” level is an intermediate voltage which is lower than the voltage of “H” level and is higher than the voltage of “L” level. The column select transistor SWU, to the gate of which the voltage of “M” level has been applied, clamps the voltage of the bit line BL at a positive potential. At this time, the potential of the bit line BL is kept at a value calculated by subtracting the threshold of the transistor SWU from the voltage corresponding to logic “M” level. In addition, the controller 11 sets the discharge signal DIS at “L”, and sets the transistors 40 and 41 in the OFF state. Thereby, the memory cell array 10 enters the active state. In addition, the controller 11 sets the read enable signal REN and sink signal SINK at “H” level, and sets the transistors 42 to 44 in the ON state. Thereby, current is supplied from the power supply terminal, which is connected to the first sense circuit and data hold circuit, to the memory cell array 10 and reference current generation circuit 23. A read current, which flows in the selected memory cell MC of the memory cell array 10, varies in accordance with the stored data (“1” data or “0” data). On the other hand, a current, which flows in the reference current generation circuit 23, is a reference current corresponding to an intermediate level between “1” data and “0” data.

At time instant t1, the controller 11 sets the sense enable signal SEN1 at “H” level, and sets the transistors 64 and 65 in the OFF state. Thereby, the first sense circuit stops the supply of current to the nodes OUT, OUTb. Then, the current to the nodes OUT, OUTb is supplied from only the power supply terminal that is connected to the data hold circuit.

At time instant t2, the controller 11 sets the sense enable signal SEN2 at “H” level, and sets the transistors 66 and 67 in the ON state. Thereby, the second sense circuit amplifies a difference between the read current flowing from the sense amplifier 18 to the memory cell array 10, and the reference current flowing from the sense amplifier 18 to the reference current generator 23. Then, the data hold circuit holds “H” level or “L” level in accordance with the result of comparison between the read current and the reference current.

At time instant t3, the controller 11 sets the output enable signals SOEb and SOE at “L” level and “H” level, respectively, and sets the transistors 68 to 71 in the ON state. Thereby, the read result of the selected memory cell, which is held in the data hold circuit, is output from the nodes OUT, OUTb.

At time t4, the controller 11 sets the output enable signals SOEb and SOE at “H” level and “L” level, respectively, and sets the transistors 68 to 71 in the OFF state.

At time t5, the controller 11 sets the discharge signal DIS at “H” level, and sets the transistors 40 and 41 in the ON state. In addition, the controller 11 sets the word line WL and the column select signals CSLU and CSLL at “L” level, and sets the cell select transistors 31 and column select transistors SWU and SWL in the OFF state. In addition, the controller 11 sets the write signal WDUP at “H” level and the write signal WDDN at “L” level, and sets the transistors 50 and 53 in the OFF state. Thereby, the memory device 1 enters a standby state and completes the read operation.

[1-3] Advantageous Effects of the First Embodiment

In the resistance change type memory such as the MRAM, if the amount of current flowing in the memory cell at the time of the read operation is large, there may be a case in which the data stored in the memory cell is destroyed.

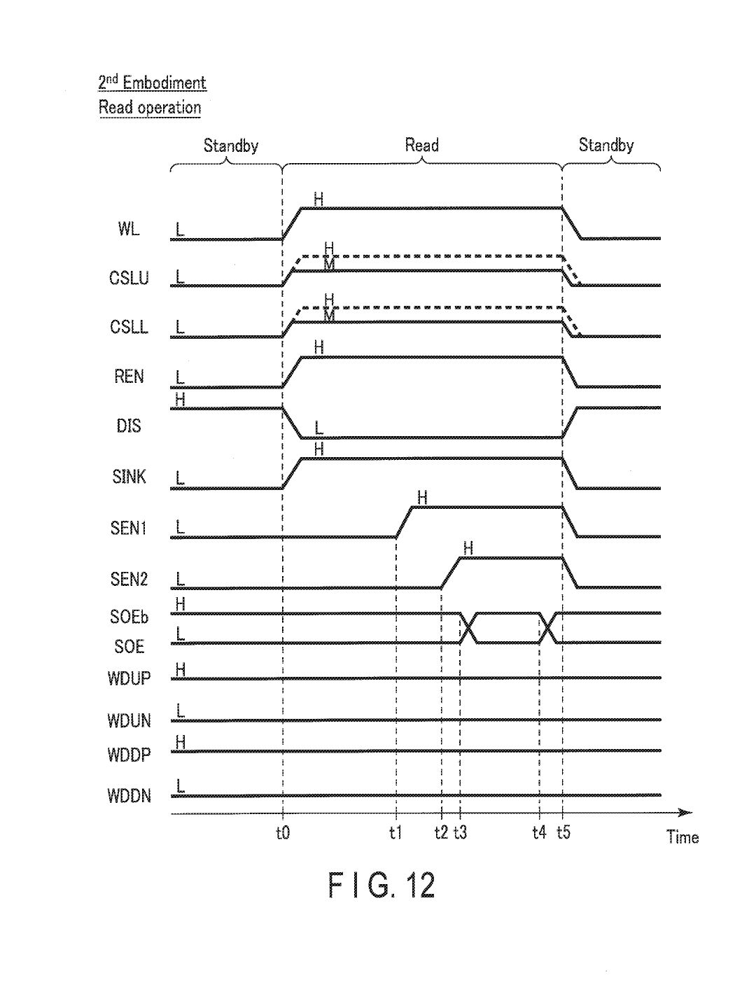

Thus, in the memory device 1 according to the first embodiment, in the read operation, the column select signal CSLU is set at an intermediate voltage. Specifically, as illustrated in FIG. 11, the column select signal CSLU of the intermediate voltage is input to the column select transistor SWU that is provided on the current path of the read current, and thereby the column select transistor SWU clamps the voltage of the bit line BL. At this time, the voltage of the bit line BL, which is clamped at the intermediate voltage, becomes lower than in the case in which this voltage is clamped at the voltage of “H” level.

Thereby, in the memory device 1 according to the first embodiment, in the read operation, the current flowing into the memory cell MC can be decreased, and the destruction of data stored in the memory cell MC can be prevented.

Moreover, in the memory device 1 according to the first embodiment, since the amount of current at the time of the read operation can be adjusted without providing a special transistor for clamping the voltage, the circuit area of the memory device 1 can be decreased.

### [2] Second Embodiment

In a memory device 1 according to a second embodiment, in a data read operation, the column select signal CSLU which are input to the column select transistor SWU that is connected to the global bit line GBL, and the column select signal CSLL which are input to the column select transistor SWL that is connected to the global source line GSL, are set at an intermediate voltage. Only different points from the first embodiment will be described below.

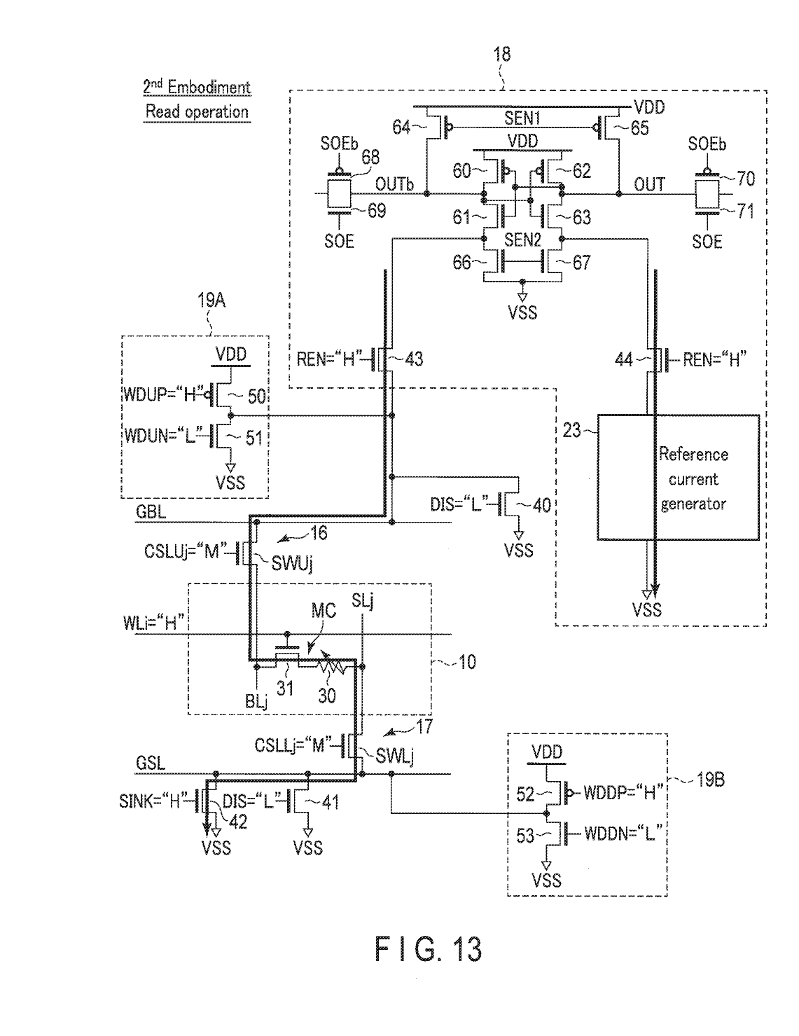

Referring to FIG. 12, a read operation of the memory device 1 according to the second embodiment is described.

At time point t0, the controller 11 sets the word line WL at “H” level and the column select signals CSLU and CSLL at “M” level, and sets the cell select transistor 31 and column select transistors SWU and SWL in the ON state. The column select transistors SWU and SWL, to the gates of which the voltage of “M” level was applied, clamp the voltages of the bit line BL and global source line GSL at positive potentials, respectively. The other operation is the same as in the read operation of the first embodiment.

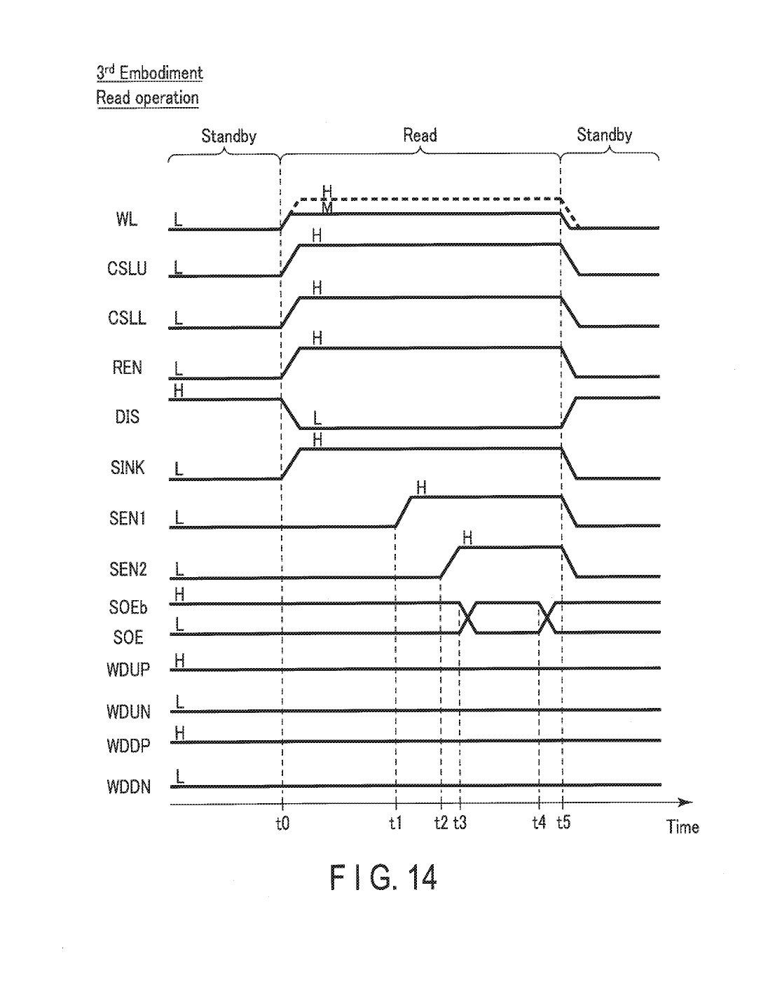

As illustrated in FIG. 13, in the read operation of the memory device 1 according to the second embodiment, column select signals CSLU and CSLL of an intermediate voltage are input to the column select transistors SWU and SWL which are provided on the current path of the read current, and thereby the voltages of the bit line BL and global source line GSL are clamped. At this time, the voltages of the bit line BL and global source line GSL, which are clamped at the intermediate voltage, become lower than in the case in which these voltages are clamped at the voltage of “H” level. If the voltage of the global source line GSL is clamped, the current flowing in the global source line GSL decreases, and accordingly the current flowing in the source line SL decreases.

Thereby, the memory device 1 according to the second embodiment can obtain the same advantageous effects as in the first embodiment. Moreover, in the second embodiment, since the current amount is adjusted by using two transistors, a finer control of current can be made than in the first embodiment.

### [3] Third Embodiment

In a memory device 1 according to a third embodiment, in a data read operation, the voltage, which is applied to a selected word line WL, is set at an intermediate voltage. Only different points from the first and second embodiments will be described below.

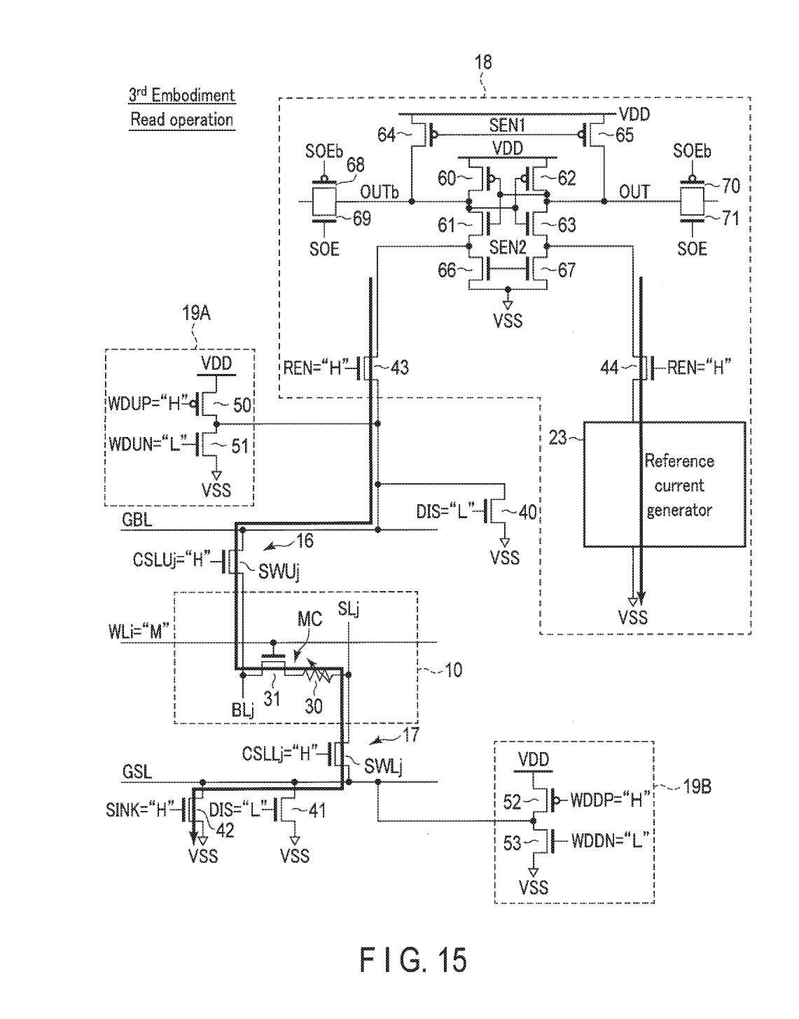

Referring to FIG. 14, a read operation of the memory device 1 according to the third embodiment is described.

At time point t0, the controller 11 sets the word line WL at “M” level and the column select signals CSLU and CSLL at “H” level, and sets the cell select transistor 31 and column select transistors SWU and SWL in the ON state. The cell select transistor 31, to the gate of which the voltage of “M” level was applied, clamps the voltage between the cell select transistor 31 and memory element 30 at a positive potential. The other operation is the same as in the read operations of the first and second embodiments.

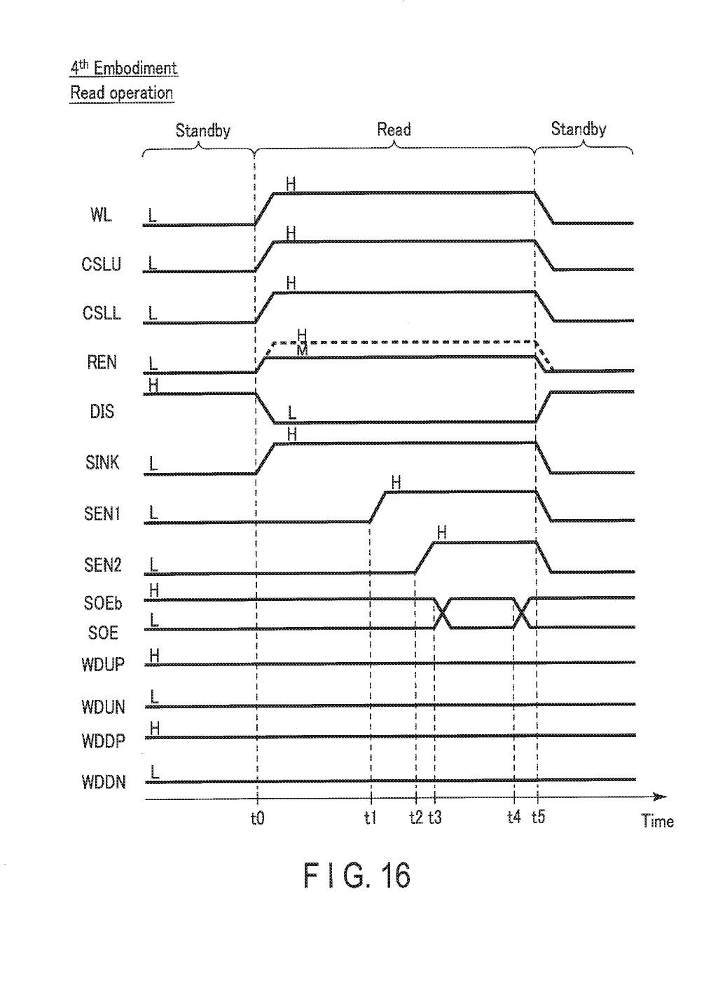

As illustrated in FIG. 15, in the read operation of the memory device 1 according to the third embodiment, the intermediate voltage is applied to the gate of the cell select transistor 31 which is provided on the current path of the read current, and thereby the cell select transistor 31 clamps the voltage between the cell select transistor 31 and memory element 30. At this time, the voltage between the cell select transistor 31 and memory element 30, which is clamped at the intermediate voltage, becomes lower than in the case in which this voltage is clamped at the voltage of “H” level. Thus, the current which is flowing in the memory cell MC decreases, and accordingly the current which is flowing in the bit line BL decreases. Thereby, the memory device 1 according to the third embodiment can obtain the same advantageous effects as in the first embodiment.

### [4] Fourth Embodiment

In a memory device 1 according to a fourth embodiment, in a data read operation, the read enable signal REN is set at an intermediate voltage. Only different points from the first to third embodiments will be described below.

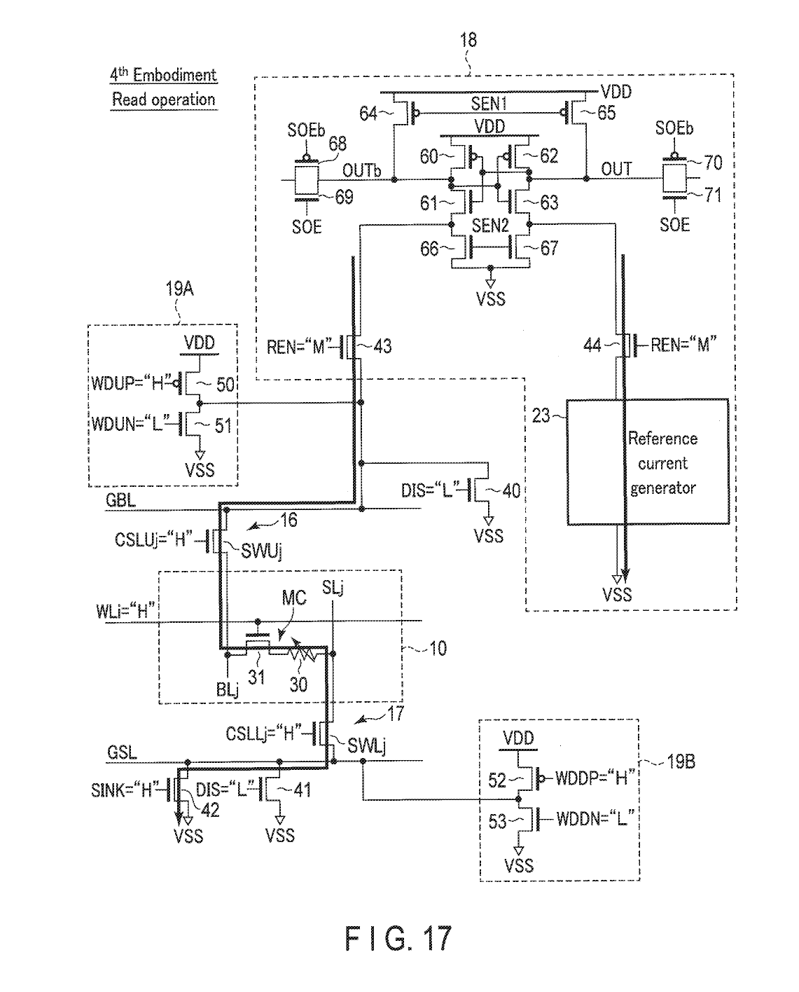

Referring to FIG. 16, a read operation of the memory device 1 according to the fourth embodiment is described.

At time point t0, the controller 11 sets the word line WL and the column select signals CSLU and CSLL at “H” level, and sets the cell select transistor 31 and column select transistors SWU and SWL in the ON state. In addition, the controller 11 sets the read enable signal REN at “M” level, sets the sink signal SINK at “H” level, and sets the transistors 42 to 44 in the ON state. The transistor 43, to the gate of which the voltage of “M” level was applied, clamps the voltage of the global bit line GBL at a positive potential. The other operation is the same as in the read operations of the first to third embodiments.

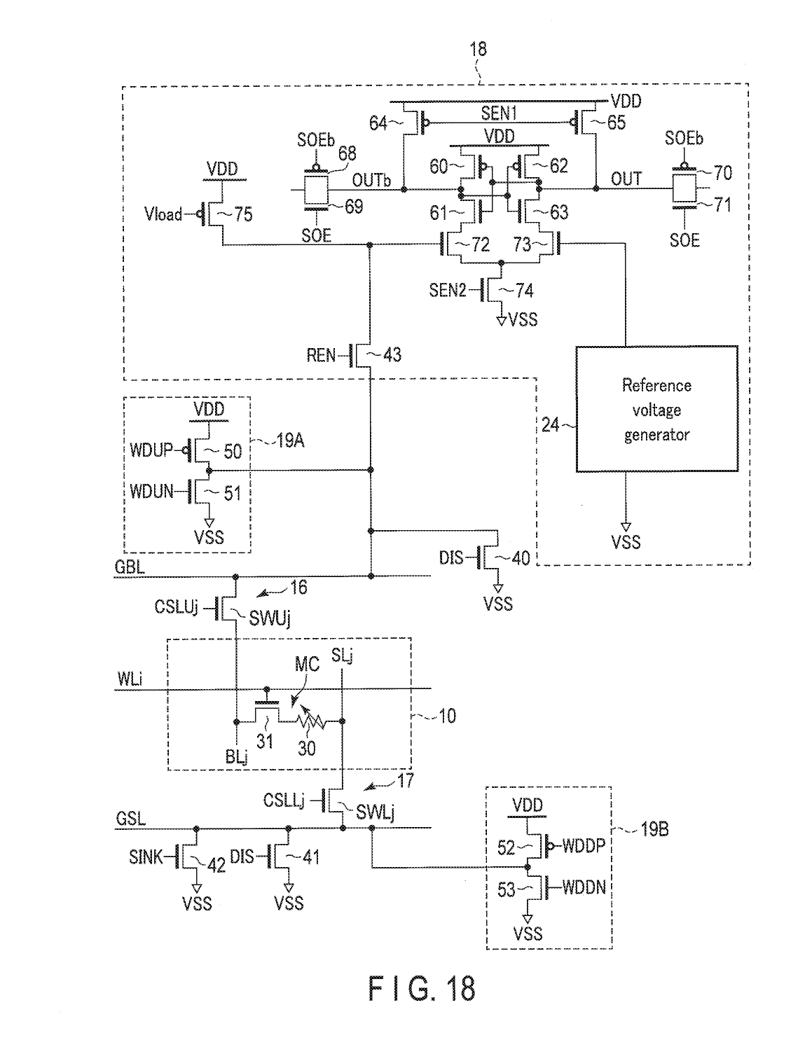

As illustrated in FIG. 17, in the read operation of the memory device 1 according to the fourth embodiment, the read enable signal REN of the intermediate voltage is applied to the transistor 43 which is provided on the current path of the read current, and thereby the transistor 43 clamps the voltage of the global bit line GBL. At this time, the voltage of the global bit line GBL, which is clamped at the intermediate voltage, becomes lower than in the case in which this voltage is clamped at the voltage of “H” level, and the voltage of the bit line BL decreases in accordance with the decrease in voltage of the global bit line GBL. Thereby, the memory device 1 according to the fourth embodiment can obtain the same advantageous effects as in the first embodiment.

### [5] Fifth Embodiment

A memory device 1 according to a fifth embodiment executes the read operation of the first to fourth embodiments on a resistance change type memory of a voltage detection type. Only different points from the first to fourth embodiments will be described below.

Referring to FIG. 18, a sense amplifier 18, which the memory device 1 according to the fifth embodiment includes, is described.

The sense amplifier 18 includes transistors 43, 60 to 65, and 68 to 74, and includes a second sense circuit having a configuration which is different from the configuration of the current detection-type sense amplifier 18.

The n-channel MOS transistors 72 to 74 function as the second sense circuit, and amplify a difference between a read voltage and a reference voltage (to be described later in detail). The drain of the transistor 72 is connected to the source of the transistor 61, and the gate of the transistor 72 is connected to the drain of the transistor 43. The drain of the transistor 73 is connected to the source of the transistor 63, and the gate of the transistor 73 is connected to a reference voltage generator 24. The drain of the transistor 74 is connected to the sources of the transistor 72 and transistor 73, the source of the transistor 74 is connected to a ground terminal, and a sense enable signal SEN2 is input to the gate of the transistor 74.

The sense amplifier 18 further includes the reference voltage generator 24 and a p-channel MOS transistor 75.

The reference voltage generator 24 generates a reference voltage having an intermediate voltage value between the cell voltage varying when the memory cell stores “1” data and the cell voltage varying when the memory cell stores “0” data. The reference voltage generator 24 includes, for example, a reference cell in which “1” data is stored, and a reference cell in which “0” data is stored, and generates the reference voltage by using these reference cells. Furthermore, the configuration of the reference voltage generator 24 is not limited to this, and may generate a reference voltage by, for example, a fixed resistor.

The transistor 75 applies a read voltage to the gate of the transistor 72. The drain of the transistor 75 is connected to a power supply terminal, the source of the transistor 75 is connected to the gate of the transistor 72, and a load signal Vload is input to the gate of the transistor 75. The load signal Vload is generated by the controller 11, and is set at, for example, “M” level.

The other configuration is the same as the configuration of the current detection-type sense amplifier 18 illustrated in the first to fourth embodiments.

The memory device 1 according to the fifth embodiment can execute the write operation and read operation by the same control as in the first to fourth embodiments. Thereby, the memory device 1 according to the fifth embodiment can obtain the same advantageous effects as in the first to fourth embodiments.

### [6] Others

The memory device according to the above-described embodiments includes a memory device includes first and second memory cells <MC, FIG. 4> including first and second transistors <31>, respectively, and third and fourth transistors. First and second memory cells include first and second variable resistance elements <30>, respectively. One end of the third and fourth transistors <SWU> is connected to the first and second memory cells, respectively. First and second voltages are applied to a gate of the third and fourth transistors, respectively, during reading data of the first memory cell. Third and second voltages are applied to a gate of the third and fourth transistors, respectively, during writing data of the first memory cell. A value of the first voltage is between the second and third voltages. A first voltage <“M” level, FIG. 10> is applied to a gate of the third transistor and a second voltage <“L” level> is applied to a gate of the fourth transistor during reading data of the first memory cell. The first voltage is higher than the second voltage. A third voltage <“H” level> is applied to the gate of the third transistor and the second voltage is applied to the gate of the fourth transistor during writing data of the first memory cell. The first voltage is lower than the third voltage.

Moreover, a reading current is supplied to the first memory cell during the reading. Writing current is supplied to the first memory cell during the writing. The reading current is lower than the writing current.

Moreover, the reading current does not change a resistance state of the first variable resistance element.

Thereby, the current flowing into the memory cell can be decreased, and the destruction of data stored in the memory cell can be prevented during reading.

Furthermore, in each of the above embodiments, operation timings at respective time instants may slightly deviate. In addition, in the read operation of the memory device 1, a timing of setting the sink signal SINK at “H” level and setting the transistor 42 in the ON state may be between the time instant t0 and time instant t1.

In the above description, the word “during reading (read operation)” means a case which is including “over the reading (read operation)”, “at a time in the reading (read operation)”, and “in a period of the reading (read operation)”. Similarly, the word “during writing (write operation)” means a case which is including “over the writing (write operation)”, “at a time in the writing (write operation)”, and “in a period of the writing (write operation)”.

In the above description, the word “connection” means “electrical connection”, and includes a case in which a connection is established with some other element intervening.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a first memory cell including a first variable resistance element and a first transistor;
a second memory cell including a second variable resistance element and a second transistor;
a third transistor, one end of the third transistor being connected to one end of the first memory cell; and
a fourth transistor, one end of the fourth transistor being connected to the second memory cell, and the other end of the fourth transistor being connected to the other end of the third transistor,
wherein a first voltage is applied to a gate of the third transistor and a second voltage is applied to a gate of the fourth transistor during reading data of the first memory cell, and the first voltage is higher than the second voltage, and
a third voltage is applied to the gate of the third transistor and the second voltage is applied to the gate of the fourth transistor during writing data of the first memory cell, and the first voltage is lower than the third voltage.

2. The device of claim 1, wherein:
reading current is supplied to the first memory cell during the reading;
writing current is supplied to the first memory cell during the writing; and
the reading current is lower than the writing current.

3. The device of claim 2, wherein the reading current does not change a resistance state of the first variable resistance element.

4. The device of claim 1, wherein the third and fourth transistors are column select transistors.

5. The device of claim 1, wherein:
the one end of the first and second memory cells are one end of the first and second transistors, respectively; and
the other end of the first and second transistors are connected to one end of the first and second variable resistance elements, respectively.

6. The device of claim 1, further comprising:
a word line being connected to the gate of the first and second transistors;
a bit line being connected to the other end of the third and fourth transistors; and
a sense amplifier being connected to the bit line.

7. The device of claim 6, wherein the sense amplifier is a sense amplifier of a current detection type or a voltage detection type.

8. The device of claim 1, further comprising a write driver being connected to the other ends of the third and fourth transistors, and configured to supply a write current to the memory cell.

9. The device of claim 1, further comprising:
a fifth transistor, one end of the fifth transistor being connected to the other end of the first memory cell; and
a sixth transistor, one end of the sixth transistor being connected to the other end of the second memory cell, the other end of the sixth transistor being connected to the other end of the fifth transistor,
wherein the first or third voltage is applied to a gate of the fifth transistor and the second voltage is applied to a gate of the sixth transistor during reading data of the first memory cell, and
the third voltage is applied to the gate of the fifth transistor and the second voltage is applied to the gate of the sixth transistor during writing data of the first memory cell.

10. The device of claim 1, wherein the device is one of a ReRAM, a PRAM, a FeNAND, an MRAM, and an iPCM.

11. A memory device comprising:
a first memory cell including a first variable resistance element and a first transistor; and
a second memory cell including a second variable resistance element and a second transistor, one end of the second memory cell being connected to one end of the first memory cell,
wherein a first voltage is applied to a gate of the first transistor and a second voltage is applied to a gate of the second transistor during reading data of the first memory cell, and the first voltage is higher than the second voltage, and
a third voltage is applied to the gate of the first transistor and the second voltage is applied to the gate of the second transistor during writing data of the first memory cell, and the first voltage is lower than the third voltage.

12. The device of claim 11, wherein:
reading current is supplied to the first memory cell during the reading;
writing current is supplied to the first memory cell during the writing; and
the reading current is lower than the writing current.

13. The device of claim 12, wherein the reading current does not change a resistance state of the first variable resistance element.

14. The device of claim 11, further comprising:
a first word line being connected to the gate of the first transistor; and
a second word line being connected to the gate of the second transistor.

15. The device of claim 11, wherein:
the one end of the first and second memory cells are one end of the first and second transistors, respectively; and
the other end of the first and second transistors are connected to one end of the first and second variable resistance elements, respectively.

16. The device of claim 11, further comprising:
a third memory cell including a third variable resistance element and a third transistor, a gate of the third transistor being connected to the gate of the first transistor;
a fourth transistor, one end of the fourth transistor being connected to the one end of the first memory cell; and
a fifth transistor, one end of the fifth transistor being connected to the third memory cell, and the other end of the fifth transistor being connected to the other end of the fourth transistor.

17. The device of claim 16, further comprising:
a bit line being connected to the other end of the fourth and fifth transistors; and
a sense amplifier being connected to the bit line.

18. The device of claim 17, wherein the sense amplifier is a sense amplifier of a current detection type or a voltage detection type.

19. The device of claim 17, further comprising a write driver connected to the bit line, and configured to supply a write current to the memory cell.

20. The device of claim 11, wherein the device is one of a ReRAM, a PRAM, a FeNAND, an MRAM, and an iPCM.
